(19) United States
(12) Patent Application Publication
(10) Pub. No.: US 2009/0272958 A1
(43) Pub. Date: Nov. 5, 2009

(54) Resistive Memory

(76) Inventors: Klaus-Dieter Ufert, Unterschleissheim (DE); Josef Willer, Riemerling (DE)

Correspondence Address: SLATER & MATSIL, L.L.P., 17950 PRESTON ROAD, SUITE 1000, DALLAS, TX, 75252, US

(21) Appl. No.: 12/114,480

(22) Filed: May 2, 2008

(51) Int. Cl. H01L 45/00

(52) U.S. Cl. 257/2; 438/104; 257/E45.003

(57) ABSTRACT

An integrated circuit including a memory cell and method of manufacturing the integrated circuit are described. The memory cell includes a diode and a resistive memory element coupled to the diode. The resistive memory element includes a thin oxide storage layer that uses multiple resistance levels to store more than one bit of information in the resistive memory element.

### BACKGROUND

Memory devices are used in essentially all computing applications and in many electronic devices. For some applications, non-volatile memory, which retains its stored data even when power is not present, may be used. For example, non-volatile memory is typically used in digital cameras, portable audio players, wireless communication devices, personal digital assistants, and peripheral devices, as well as for storing firmware in computers and other devices.

A wide variety of memory technologies have been developed. Non-volatile memory technologies include flash memory, magnetoresistive random access memory (MRAM), phase change random access memory (PCRAM), conductive bridging random access memory (CBRAM), and carbon memory. Due to the great demand for memory devices, researchers are continually improving memory technology, and developing new types of memory, including new types of non-volatile memory.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show a resistive memory element in which a conductive filament is formed through a transition metal oxide layer;

FIG. 2 shows a portion of a memory array, including a memory cell that uses a resistive memory element;

FIG. 3 shows a view of a multi-level memory device including a memory cell that uses a resistive memory element;

FIG. 4 shows a memory cell using a resistive memory element, in accordance with an embodiment of the invention;

FIG. 5 shows a memory cell using a resistive memory element, in accordance with an embodiment of the invention;

FIG. 6 is a block diagram of a method for manufacturing an integrated circuit memory device in accordance with an embodiment of the invention;

FIGS. 7A-7C show views of an integrated circuit memory device in accordance with an embodiment of the invention at various stages of the manufacturing process;

FIG. 8 is a block diagram of a method of storing information in accordance with an embodiment of the invention; and

FIGS. 9A and 9B show a memory module and a stackable memory module, respectively, which may use memory cells in accordance with an embodiment of the invention.

### DETAILED DESCRIPTION OF ILLUSTRATIVE EMBODIMENTS

The scale of electronic devices is constantly being reduced. For memory devices, conventional technologies, such as flash memory and DRAM, which store information based on storage of electric charges, may reach their scaling limits in the foreseeable future. Additional characteristics of these technologies, such as the high switching voltages and limited number of read and write cycles of flash memory, or the limited duration of the storage of the charge state in DRAM, pose additional challenges. To address some of these issues, researchers are investigating memory technologies that do not use storage of an electrical charge to store information. One such technology is a resistive memory based on the bistable resistance change in transition metal oxide layers or other thin oxide layers. As will be described below, in certain transition metal oxide materials, in response to the application of an adequate voltage, a conductive path or filament may be formed or removed within the material, due to thermal electronic exchange effects. The formation and removal of this conductive filament is coupled with a thermistor effect, which induces the bistable switching process, due to the inhomogeneous temperature distribution in the transition metal oxide material in response to the application of a voltage.

Among the transition metal chalcogenides, NiO is of particular interest for this application, due to its large band gap of approximately 4.5 eV. At room temperature, NiO in its stoichiometric state is a good isolating semiconductor, which forms its relatively large band gap by means of hybridization of relatively strongly localized 3d electrons with O 2p electron bands. Additionally, NiO has a region with negative differential resistance and monostable switching in the current-voltage (I−U) characteristic due to the steepness of its resistance-temperature characteristic in response to the application of an appropriate voltage due to the thermistor effect (σ˜e^{-ΔE/kT}).

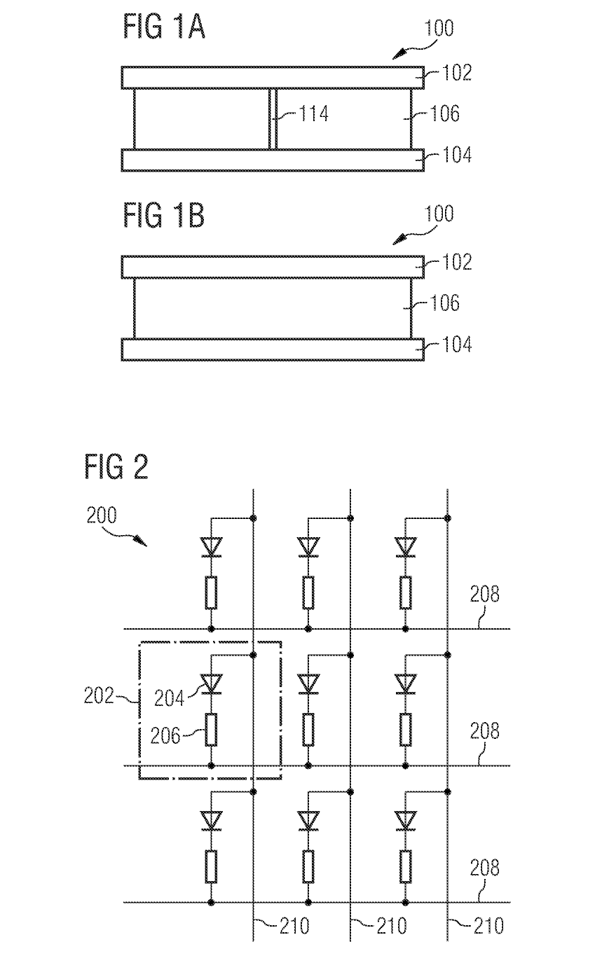

FIG. 1A shows a resistive memory element 100 of the type discussed above. The resistive memory element 100 includes a top contact 102, a bottom contact 104, and a thin oxide storage layer 106 located between the top contact 102 and the bottom contact 104. The thin oxide storage layer 106 may have a thickness of approximately 10 to 20 nm, and may include oxide materials such as silicon oxide or any of a number of transition metal oxide compounds, such as NiO, TiO₂, HfO₂, ZrO₂, Nb₂O₅, Ta₂O₅, or other suitable materials.

When a voltage above a “SET” voltage is applied across the thin oxide storage layer 106, a conductive filament 114 is formed within the layer, placing the resistive memory element 100 in an “ON” state by dramatically reducing the resistance of the transition metal oxide storage layer 106. For example, a SET voltage of approximately 2V applied across an NiO film with a thickness between approximately 20 nm and approximately 100 nm may cause the resistance of the film to drop from approximately 1 KΩ to 10 KΩ (depending on the thickness of the layer) to less than approximately 100Ω.

As shown in FIG. 1B, when a “RESET” voltage is applied across the thin oxide storage layer 106 in the “ON” state, the conductive filament 114 is removed, returning the resistive memory element 100 to an “OFF” state, and increasing the resistance of the thin oxide storage layer 106. The “RESET” voltage for use with a thin oxide layer including an NiO film may be approximately 1V.

To determine the current memory state of the resistive memory element 100, a sensing current may be applied through the resistive memory element 100. The sensing current encounters a high resistance if no filament 114 exists within the resistive memory element 100, and a low resistance when a filament 114 is present. A high resistance may, for example, represent “0”, while a low resistance represents “1”, or vice versa.

FIG. 2 shows an illustrative portion of a memory array 200, including numerous memory cells 202 that include a resistive memory element, such as is described above. Each memory cell 202 is located at the intersection of a bit line 208 and a word line 210, and includes a select diode 204 and a resistive memory element 206.

Use of the select diode 204 in each memory cell 202 permits a specific memory cell to be selected for a write, reset, or read operation, without disturbing the state of other memory cells. For example, to write to the memory cell, a “WRITE” voltage, higher than a threshold (forward) voltage of the select diode 204, but lower than its breakdown (reverse) voltage is applied to the bit line 208 of the selected memory cell. This same voltage is applied to each of the word lines 210 other than the one associated with the selected cell. A lower voltage (e.g., 0V) is applied to the word line 210 associated with the selected cell, and to each of the bit lines 208 other than the one associated with the selected cell. This results in the “WRITE” voltage (and current) being applied across the selected cell. No current flows through non-selected cells, because the potential across the other cells is lower than the breakdown voltage of the select diode 204. Similar processes can be used to select a memory cell for reset or read operations.

A memory array such as the memory array 200, in which memory cells are located at the intersections of the bit lines and word lines, may be referred to as a cross point array. It will be understood that other configurations for memory cells or memory arrays may be used. For example, in many memory devices, a select transistor is used instead of a select diode. Additionally, depending on the design of the memory cell and array, a variety of methods may be used to apply the appropriate voltages and currents for reading, writing, and resetting the state of a memory cell.

One challenge for memory technologies is the limited packing density of memory cells. Increasing the packing density increases the number of memory cells that can be placed on a single integrated circuit device, and thus increases the amount of data that the device can store. Generally, the packing density can be increased by decreasing the scale of the memory cells. Additionally, the number of memory cells on an integrated circuit device may be increased by stacking the memory cells in a vertical arrangement, so that there are memory cells located on a plurality of levels, in a three-dimensional arrangement.

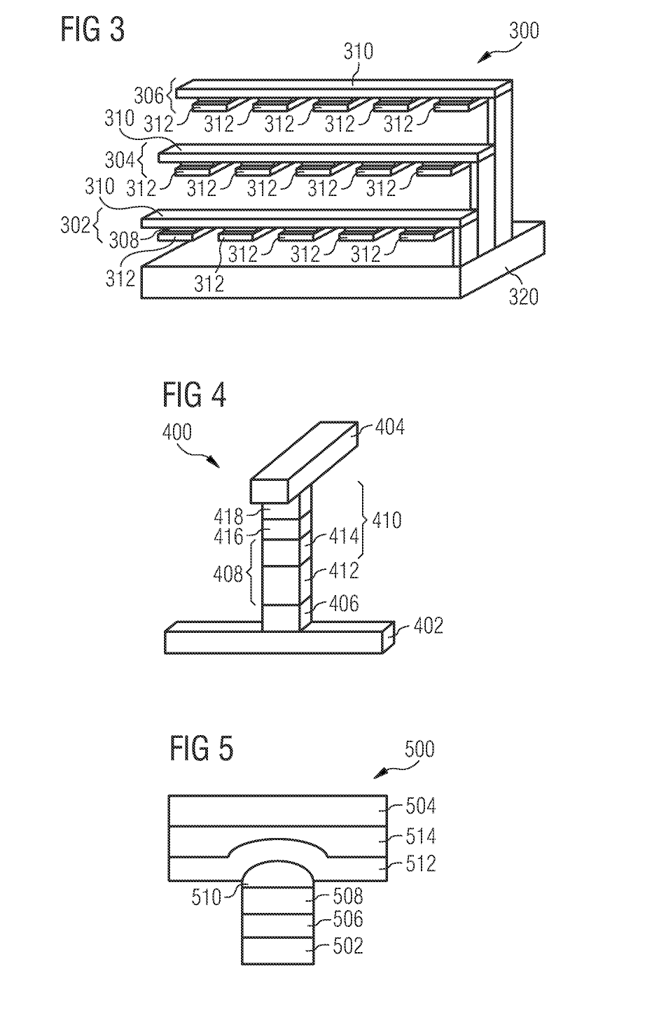

A multi-level array of this sort is illustrated in FIG. 3. The multi-level memory array 300 includes a memory level 302, a second memory level 304, and a third memory level 306, formed above a substrate 320. Each of the memory levels 302, 304 and 306 includes numerous memory cells 308, located at the intersections of word lines 310 and bit lines 312. While the multi-level array achieves a high packing density of memory cells, the additional space taken to provide contacts between the substrate 320 and the bit lines 312 and word lines 310 reduces the density that can be achieved by such an arrangement. Such multi-level memory devices have limited potential for scaling below a 100 nm cell size in current technologies. Additionally, multi-level storage may demand use of more complex select logic for the various levels. This complex select logic is typically located on the substrate 320, and may require at least two wiring levels on the substrate 320 for the select logic.

The increased complexity of multi-level memory devices is also reflected in increased process expenditure and reduced yield. Manufacturing experience suggests that the yield may be reduced by approximately 5% per level for manufacturing multi-level memory devices.

In accordance with an embodiment of the invention, memory density can be increased in a resistive memory device employing a resistive memory element, as described above, by storing multiple bits of information in each such resistive memory element, rather than by placing the memory elements in various layers. This can be achieved by controlling the storage layer (e.g., a thin oxide storage layer) of the memory element using various voltage levels via a diode coupled in series with the storage layer. By carefully controlling the power density applied to the storage layer, numerous bistable states with different on-levels can be used. Thus, depending on the voltage applied, the resistance of the storage layer can be in numerous distinguishable resistance levels, between a very high resistance “off” state to a quasi-metallic “on” state. These intermediate resistance levels may be used to store additional bits of information in a single storage layer. For example, with a total of four resistance levels (“off”, “on”, and two intermediate levels), two bits of information can be stored, while with a total of eight resistance levels (“off”, “on”, and six intermediate levels), three bits of information can be stored. In general, n bits of information can be stored using 2ⁿ resistance levels.

In accordance with some embodiments of the invention, there is a resistance difference of around six to eight orders of magnitude between the high resistance “off” state and quasi-metallic “on” state of a resistive memory element that uses a thin transition metal oxide (TMO) storage layer. A difference of approximately a factor of three in resistivity is sufficient to clearly distinguish two different resistance levels. Thus, a resistive memory element, such as is described above, should be able to store approximately four bits of information, though fewer or more bits of information may be stored in some embodiments.

FIG. 4 shows a view of a memory cell in accordance with one embodiment of the invention. The memory cell 400 is disposed between a word line 402 and a bit line 404, and includes a bottom contact 406, a diode 408, and a resistive memory element 410. The bottom contact may include a layer of a conductive material, such as tungsten (W) or WSi, having a thickness of approximately 20 to 30 nm. The diode 408 includes a semiconductor layer 412 having an n+ to n− gradient, and a metallic layer 414, to form a Schottky barrier. The semiconductor layer 412 may include a material such as poly-Si having an n+ to n− gradient, and a thickness of approximately 50 nm. The metallic layer 414 may include a metallic conductive material, such as PtSi, and have a thickness of approximately 30 nm. In some embodiments, the metallic layer 414 also serves as the bottom contact of the memory element 410, and as will be described below, may have a rounded configuration to facilitate field strength control for setting numerous resistance levels.

The memory element 410 includes a bottom contact, which in this embodiment is the same as the metallic layer 414 of the diode 408. Sharing the metallic layer 414 between the diode 408 and the memory element 410 reduces the number of fabrication steps involved in manufacturing the memory cell 400, which may lead to less manufacturing expense and fewer manufacturing errors. The memory element 410 also includes a thin oxide storage layer 416, which may include silicon oxide, a TMO material, such as NiO, TiO₂, HfO₂, ZrO₂, Nb₂O₅, Ta₂O₅, or other suitable materials. Using such a material, the storage layer 416 may have a thickness of approximately 10 to 20 nm. In some embodiments that use a TMO material in the storage layer 416, the TMO material may have an oxygen deficiency.

The memory element 410 also includes a top contact 418, which may include a conductive material, such as platinum (Pt) or palladium (Pd). Using one of these materials, the thickness of the top contact 418 may be approximately 30 nm.

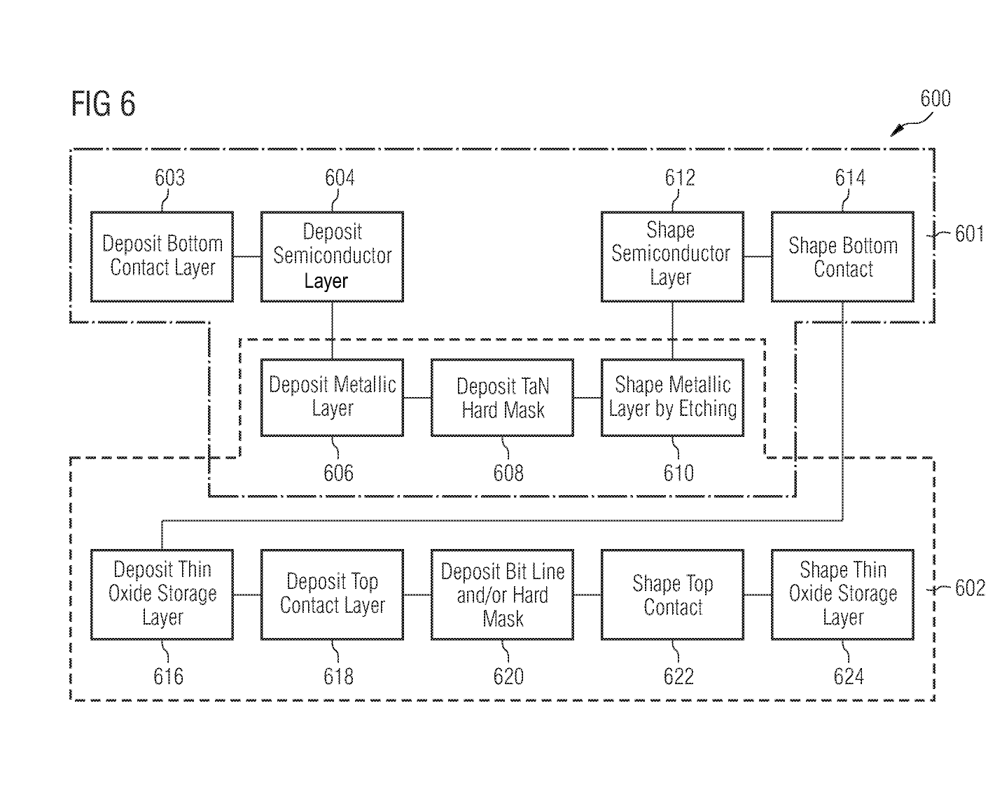

FIG. 5 shows another view of a memory cell 500 in accordance with an embodiment of the invention. As above, the memory cell 500 is located between a word line 502 and a bit line 504. The memory cell 500 includes a bottom contact 506, including a conductive material such as WSi, with a thickness of approximately 20-30 nm. Above the bottom contact 506 is a semiconductor layer 508 having an n+ to n− gradient, and a thickness of approximately 50 nm.

A metallic layer 510 is disposed above the semiconductor layer 508, to form a Schottky barrier. Thus, the semiconductor layer 508 and the metallic layer 510 combine to form a Schottky diode. The metallic layer 510 may include a metallic material, such as PtSi, and have a thickness of approximately 30 nm at its thickest point.

The metallic layer 510 also forms a bottom contact for a memory element including a thin oxide storage layer 512, which is disposed above the metallic layer/bottom contact 510. The storage layer 512 may include silicon oxide, a TMO material, such as NiO, TiO₂, HfO₂, ZrO₂, Nb₂O₅, Ta₂O₅, or other suitable materials, and have a thickness of approximately 10 to 20 nm. In some embodiments the TMO material of the storage layer 512 may have an oxygen deficiency.

A top contact 514 is disposed above the storage layer 512. The top contact 514 includes a conductive material, such as Pt or Pd, and may be approximately 30 nm thick at its thickest point. The metallic layer 510, storage layer 512, and top contact 514 together form a resistive memory element that can store multiple bits of information, as described above.

As can be seen in FIG. 5, in some embodiments, the metallic layer 510 has a rounded configuration. This rounded configuration facilitates programming the storage layer 512 into various resistance levels used to store multiple bits of information in the storage layer 512. A non-rounded configuration would have areas of higher and lower field strength, including, for example, field strength spikes at the etched edges of such a configuration. In accordance with an embodiment of the invention, by using a rounded configuration for the metallic layer 512, such variation in field strength is reduced, resulting in a greater degree of control over the field strength and current density in the storage layer 512. This may result in more reliable setting of various resistance levels in the storage layer 512, facilitating multi-bit storage.

FIG. 6 shows a flow diagram of a method 600 for manufacturing an integrated circuit including a memory cell such as is described above, in accordance with an embodiment of the invention. The method 600 is compatible with a standard CMOS process. Manufacture of the integrated circuit prior to formation of a memory cell in accordance with an embodiment of the invention, can be achieved using well known conventional techniques, and will not be further described here. The method 600 assumes that a word line has already been formed using such conventional techniques.

The method 600 includes a first part 601, including steps 603 through 614 as described below, in which a diode is formed. In a second part 602 of the method 600, including steps 606 through 610 and steps 616 through 624, a resistive memory element is formed. Because the metallic layer of the diode also serves as the bottom contact of the resistive memory element, steps 606 through 610, in which the metallic layer is formed, are shared by the first part 601 and the second part 602 of the method 600.

In step 603, a bottom contact layer is deposited. The bottom contact layer may be formed by depositing a conductive material, such as WSi, to a thickness of approximately 20 to 30 nm using a low pressure chemical vapor deposition (LPCVD) process.

In step 604, a semiconductor layer having an n+ to n− doping gradient is deposited. This can be achieved by depositing poly silicon using LPCVD to a thickness of approximately 50 nm. The doping gradient is set in-situ by phosphorus doping beginning with an n+ area having a concentration of greater than 10²/cm³ for the low resistance portion adjacent to the WSi bottom contact layer. This is followed by an n− area having a concentration of approximately 10¹⁷/cm³ for forming a Schottky diode with the PtSi metallic layer that is formed above the semiconductor layer.

In step 606, a metallic layer is deposited. The metallic layer may include PtSi, which may be formed by depositing poly silicon using LPCVD, followed by DC sputtering of Pt. A rapid thermal anneal (RTA) process at a temperature of approximately 600° C. may then be used on the layers of poly silicon and Pt to form a PtSi metallic layer. The PtSi metallic layer also serves as a bottom contact for the resistive memory element. The rounded configuration of the PtSi metallic layer is achieved during structuring of the layer stack, in the steps described below, by mask erosion.

In step 608, a TaN hard mask is deposited, and a photo mask is used to structure the layer stack by shaping the TaN hard mask using fluorine chemistry. Oxygen may be mixed with the etching gas to minimize etching of the Pt layer.

In step 610, the PtSi metallic layer, which serves both as part of the Schottky diode and as a bottom contact for the memory element, is shaped. This is achieved using chlorine/oxygen chemistry for reactive ion etching (RIE). In some embodiments, a hot cathode, having a temperature of approximately 250° C. may be used in the etching, for example, in a DPS hot cathode reactor. This process leaves the PtSi metallic layer with a rounded shape, as discussed above.

In step 612, the doped semiconductor layer is shaped by etching. This may be accomplished using RIE with etch gasses containing fluorine, chlorine, or bromine. Depending on the etch gasses used, the TaN hard mask also will be removed in this step or the next.

In step 614, the WSi bottom contact is shaped by etching. RIE with fluorine chemistry can be used to etch the WSi bottom contact layer. Slight etching of the layer below the bottom contact layer, including word lines that may include tungsten (W), may be prevented by using optical emissions spectroscopy (actinometry) to stop the etch process in the absence of Si lines.

Next, in step 616, the thin oxide storage layer is deposited. This is done, for example, by depositing a TMO material, such as NiO₁₋ₓ or ZrO₂₋ₓ by reactive co-sputtering of an appropriate metal target in an Ar/O₂ gas mixture. DC sputtering may be used to operate the plasma, though MF or RF sputtering could also be used. The sputter pressure may be set to approximately 4-5×10⁻³ mbar, and the substrate temperature may be approximately 250° C. during the sputtering. The oxygen partial pressure may be set during the sputtering such that the resistivity of the oxide layer is set to approximately 10⁶ to 10⁸ ohm-cm. Sputtering continues until the layer thickness is approximately 10 to 20 nm.

In step 618, a Pt top contact layer is deposited. This is achieved by sputtering using a Pt target under standard process conditions (e.g., room temperature, Ar gas at approximately 4×10⁻³ mbar). The top layer is deposited to a thickness of approximately 30 nm.

In step 620 a tungsten (W) bit line and/or a hard mask is deposited. The W bit line may be deposited using a DC sputtering process.

In step 622, the Pt top contact is shaped using chlorine/oxygen chemistry in an RIE process, with a hot cathode (approximately 250° c, for example, in a DPS hot cathode reactor).

Finally, in step 624, the thin oxide storage layer is shaped by etching. For etching a thin oxide layer including a TMO material, a conventional fluorine etching technique may be used.

After the memory cell has been formed as described above, manufacturing of the integrated circuit may continue, using known conventional techniques. Although the above-described method discusses use of specific techniques, such as RIE for etching, it will be recognized that there are other well known ways of carrying out the same or similar processes. For example, there are a variety of known techniques for etching. The specific techniques mentioned above are intended only as examples, and other techniques now known or hereafter developed may be used to carry out the same or similar processes.

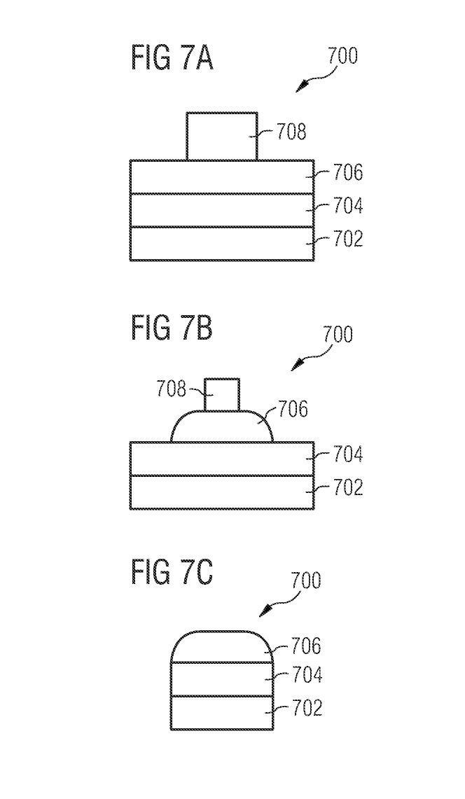

FIGS. 7A-7C show the integrated circuit memory cell after intermediate steps of the above-described method. In particular, shaping of the PtSi metallic layer and shaping of the doped semiconductor layer and bottom contact are illustrated, corresponding to steps 608 through 614 as described above with reference to FIG. 6.

In FIG. 7A the integrated circuit memory cell 700 is partially formed, including a WSi bottom contact layer 702, a doped semiconductor layer 704, including poly silicon having an n+ to n− gradient, and a PtSi metallic layer 706. A TaN hard mask 708 has been deposited and formed, for use in shaping the layers below the hard mask 708.

In FIG. 7B the PtSi metallic layer 706 has been shaped. This is achieved using chlorine/oxygen chemistry in an RIE process, using a hot cathode having a temperature of approximately 250° C. The rounded configuration of the PtSi metallic layer 706 is achieved by mask erosion.

In FIG. 7C the doped semiconductor layer 704 and the WSi bottom contact layer 702 have been shaped by etching. For the doped semiconductor layer 704, an RIE process is used to etch the layer, using etch gasses containing fluorine, chlorine, or bromine. The WSi bottom contact layer 702 is shaped using RIE with fluorine chemistry. During the shaping of the doped semiconductor layer 704 and the WSi bottom contact layer 702, the TaN hard mask also is removed.

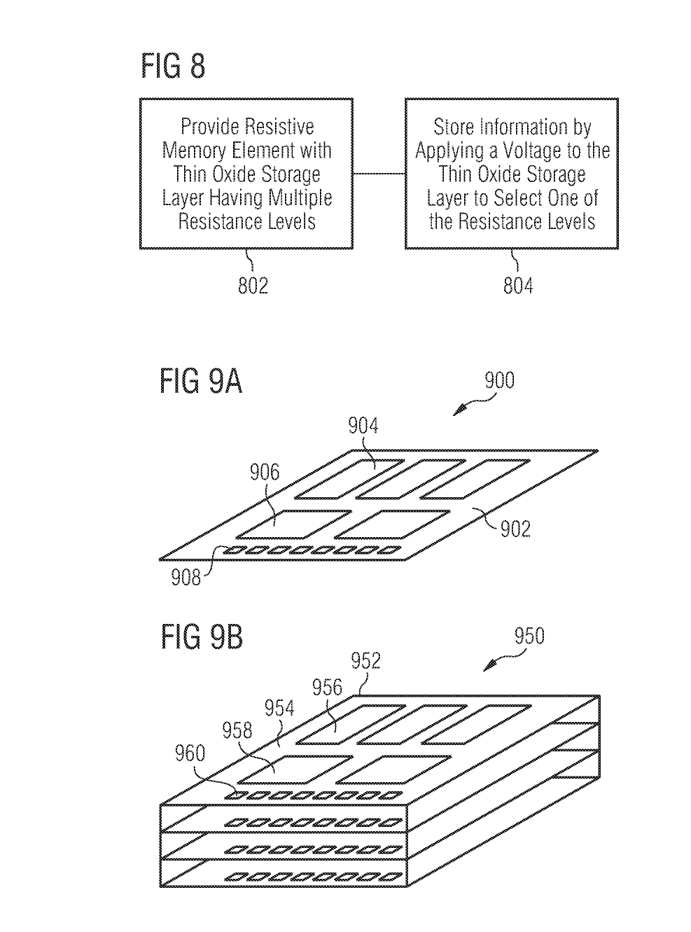

FIG. 8 shows a block diagram of a method for storing information according to an embodiment of the invention. In step 802, a resistive memory element, as described above, is provided. The memory element includes a top contact, a bottom contact having a rounded configuration, and a thin oxide storage layer that uses multiple resistance levels to store more than one bit of information in the memory element. In step 804, information is stored by applying a voltage to the thin oxide storage layer to select one of the multiple resistance levels. As explained above, by using multiple resistance levels, more than one bit of information may be stored in such a memory element.

Memory cells in accordance with an embodiment of the invention, such as described above, may be used in memory devices that contain large numbers of such cells. These cells may, for example, be organized into an array of memory cells having numerous rows and columns of cells, each of which stores more than one bit of information. Memory devices of this sort may be used in a variety of applications or systems. As shown in FIGS. 9A and 9B, in some embodiments, memory devices such as those described herein may be used in modules. In FIG. 9A, a memory module 900 is shown, on which one or more memory devices 904 are arranged on a substrate 902. Each memory device 904 may include numerous memory cells in accordance with an embodiment of the invention. The memory module 900 may also include one or more electronic devices 906, which may include memory, processing circuitry, control circuitry, addressing circuitry, bus interconnection circuitry, or other circuitry or electronic devices that may be combined on a module with a memory device 904. Additionally, the memory module 900 includes multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more memory devices 956, arranged on a stackable substrate 954. Each of the memory devices 956 contains memory cells that employ memory elements in accordance with an embodiment of the invention. The stackable memory module 952 may also include one or more electronic devices 958, which may include memory, processing circuitry, control circuitry, addressing circuitry, bus interconnection circuitry, or other circuitry or electronic devices that may be combined on a module with a memory device 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

Thus, in one embodiment, an integrated circuit is provided, including a memory cell that includes a diode and a resistive memory element coupled to the diode. The resistive memory element includes a thin oxide storage layer that uses multiple resistance levels to store more than one bit of information in the resistive memory element.

In some embodiments, the thin oxide storage layer comprises silicon oxide. In some embodiments, the thin oxide storage layer comprises a transition metal oxide material. In some of these embodiments, the transition metal oxide material is selected from a group consisting of NiO, TiO₂, HfO₂, ZrO₂, Nb₂O₅, and Ta₂O₅. In some embodiments, the transition metal oxide material has an oxygen deficiency.

In some embodiments, the thin oxide storage layer has a thickness of approximately 10 nm to approximately 20 nm. In some embodiments, the thin oxide storage layer switches between the multiple resistance levels based on a voltage applied to the thin oxide storage layer.

In some embodiments, the resistive memory element includes a bottom contact having a rounded configuration. In some embodiments, the diode includes a semiconductor layer and a metallic layer, and the resistive memory element uses the metallic layer of the diode as a bottom contact for the resistive memory element.

In some embodiments of the invention, a method of manufacturing an integrated circuit is provided. The method includes forming a diode, and forming a resistive memory element coupled to the diode, the resistive memory element including a thin oxide storage layer that uses multiple resistance levels to store more than one bit of information in the resistive memory element.

In some embodiments, forming the diode includes depositing a semiconductor layer having an n+ to n− doping gradient, and depositing a metallic layer in contact with the semiconductor layer to form a Schottky barrier. Some such embodiments further include shaping the metallic layer to have a rounded configuration. In some embodiments, shaping the metallic layer includes using mask erosion to produce a rounded configuration for the metallic layer.

Some embodiments further include using the metallic layer of the diode as a bottom contact layer of the resistive memory element. In some embodiments, depositing a metallic layer includes depositing a material including PtSi.

In some embodiments, forming the resistive memory element includes depositing a thin oxide storage layer. In some embodiments, depositing a thin oxide storage layer includes depositing a transition metal oxide material. In some embodiments, depositing a transition metal oxide material includes depositing a material selected from a group consisting of NiO, TiO₂, HfO₂, ZrO₂, Nb₂O₅, and Ta₂O₅. In some embodiments, depositing a thin oxide storage layer includes depositing a thin oxide storage layer having a thickness of approximately 10 nm to approximately 20 nm. In some embodiments, depositing a thin oxide storage layer includes depositing a thin oxide storage layer having a resistivity of approximately 106 to approximately 108 ohm-cm.

In another embodiment, an integrated circuit is provided, including a resistive memory element including a bottom contact having a rounded configuration, and a thin oxide storage layer disposed above the bottom contact, the thin oxide storage layer using multiple resistance levels to store more than one bit of information in the resistive memory element.

In some embodiments, the thin oxide storage layer includes a transition metal oxide material. In some embodiments, the transition metal oxide material is selected from a group consisting of NiO, TiO₂, HfO₂, ZrO₂, Nb₂O₅, and Ta₂O₅. In some embodiments, the transition metal oxide material has an oxygen deficiency. In some embodiments, the thin oxide storage layer switches between the multiple resistance levels based on a voltage applied to the thin oxide storage layer.

In some embodiments, the integrated circuit further includes a diode electrically connected in series with the resistive memory element. In some embodiments, the diode may include a semiconductor layer and a metallic layer that serves as the bottom contact of the resistive memory element.

A further embodiment provides a memory cell including a diode including a semiconductor layer and a metallic layer, and a resistive memory element including a thin oxide storage layer that uses multiple resistance levels to store more than one bit of information in the resistive memory element. In some embodiments, the metallic layer of the diode also serves as a bottom contact of the resistive memory element.

In some embodiments, the thin oxide storage layer includes a transition metal oxide material. In some of these embodiments, the transition metal oxide material is selected from a group consisting of NiO, TiO₂, HfO₂, ZrO₂, Nb₂O₅, and Ta₂O₅. In some embodiments, the transition metal oxide material may have an oxygen deficiency. In some embodiments, the thin oxide storage layer switches between the multiple resistance levels based on a voltage applied to the thin oxide storage layer.

In some embodiments, the metallic layer has a rounded configuration.

In a further embodiment, the invention provides a memory element that includes a bottom contact having a rounded configuration, a thin oxide storage layer that uses multiple resistance levels to store more than one bit of information in the memory element, and a top contact. In some embodiments, the thin oxide storage layer comprises a transition metal oxide material. In some embodiments, the thin oxide storage layer switches between the multiple resistance levels based on a voltage applied to the thin oxide storage layer.

In a further embodiment, the invention provides a method of storing information including providing a memory element that includes a bottom contact having a rounded configuration, a thin oxide storage layer that uses multiple resistance levels to store more than one bit of information in the memory element, and a top contact. The method further includes storing information by applying a voltage to the thin oxide storage layer to select one of the multiple resistance levels. In some embodiments, providing a memory element includes providing a memory element wherein the thin oxide storage layer includes a transition metal oxide material.

In another embodiment of the invention, a memory module is provided, including a plurality of integrated circuits. The integrated circuits include a memory cell that includes a diode and a resistive memory element coupled to the diode. The resistive memory element includes a thin oxide storage layer that uses multiple resistance levels to store more than one bit of information in the resistive memory element. In some embodiments, the thin oxide storage layer includes a transition metal oxide material. In some embodiments, the thin oxide storage layer switches between the multiple resistance levels based on a voltage applied to the thin oxide storage layer. In some embodiments, the resistive memory element includes a bottom contact having a rounded configuration. In some embodiments, the diode includes a semiconductor layer and a metallic layer, and the resistive memory element uses the metallic layer of the diode as a bottom contact for the resistive memory element. In some embodiments, the memory module is stackable.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
a memory cell comprising a diode and a resistive memory element coupled to the diode, the resistive memory element comprising an oxide storage layer that uses multiple resistance levels to store more than one bit of information in the resistive memory element.

2. The integrated circuit of claim 1, wherein the oxide storage layer comprises silicon oxide.

3. The integrated circuit of claim 1, wherein the oxide storage layer comprises a transition metal oxide material.

4. The integrated circuit of claim 3, wherein the transition metal oxide material comprises selected from the group consisting of NiO, TiO₂, HfO₂, ZrO₂, Nb₂O₅, and Ta₂O₅.

5. The integrated circuit of claim 3, wherein the transition metal oxide material has an oxygen deficiency.

6. The integrated circuit of claim 1, wherein the oxide storage layer has a thickness of approximately 10 nm to approximately 20 nm.

7. The integrated circuit of claim 1, wherein the oxide storage layer switches between the multiple resistance levels based on a voltage applied to the oxide storage layer.

8. The integrated circuit of claim 1, wherein the resistive memory element comprises a bottom contact having a rounded configuration.

9. The integrated circuit of claim 1, wherein the diode comprises a semiconductor layer and a metallic layer, and wherein the resistive memory element uses the metallic layer of the diode as a bottom contact for the resistive memory element.

10. A method of manufacturing an integrated circuit, the method comprising:
forming a diode; and
forming a resistive memory element coupled to the diode, the resistive memory element comprising an oxide storage layer that uses multiple resistance levels to store more than one bit of information in the resistive memory element.

11. The method of claim 10, wherein forming the diode comprises:
depositing a semiconductor layer having an n+ to n− doping gradient; and
depositing a metallic layer in contact with the semiconductor layer to form a Schottky barrier.

12. The method of claim 11, further comprising shaping the metallic layer to have a rounded configuration.

13. The method of claim 12, wherein shaping the metallic layer comprises using mask erosion to produce a rounded configuration for the metallic layer.

14. The method of claim 11, wherein the metallic layer of the diode is used as a bottom contact layer of the resistive memory element.

15. The method of claim 11, wherein depositing a metallic layer comprises depositing a material comprising PtSi.

16. The method of claim 10, wherein forming the resistive memory element comprises depositing the oxide storage layer.

17. The method of claim 16, wherein depositing the oxide storage layer comprises depositing a transition metal oxide material.

18. The method of claim 17, wherein depositing the transition metal oxide material comprises depositing a material selected from the group consisting of NiO, TiO₂, HfO₂, ZrO₂, Nb₂O₅, and Ta₂O₅.

19. The method of claim 16, wherein depositing the oxide storage layer comprises depositing an oxide storage layer having a thickness of approximately 10 nm to approximately 20 nm.

20. The method of claim 16, wherein depositing the oxide storage layer comprises depositing an oxide storage layer having a resistivity of approximately 106 to approximately 108 ohm-cm.

21. An integrated circuit comprising:
a resistive memory element comprising a bottom contact having a rounded configuration, and an oxide storage layer disposed above the bottom contact, the oxide storage layer using multiple resistance levels to store more than one bit of information in the resistive memory element.

22. The integrated circuit of claim 21, wherein the oxide storage layer comprises a transition metal oxide material.

23. The integrated circuit of claim 22, wherein the transition metal oxide material has an oxygen deficiency.

24. The integrated circuit of claim 21, wherein the oxide storage layer switches between the multiple resistance levels based on a voltage applied to the oxide storage layer.

25. The integrated circuit of claim 21, further comprising a diode electrically connected in series with the resistive memory element, the diode comprising a semiconductor layer and a metallic layer that serves as the bottom contact of the resistive memory element.
